(19) United States
(12) Patent Application Publication
(10) Pub. No.: US 2026/0233987 A1
(43) Pub. Date: Aug. 13, 2026

(54) ALIGNMENT OF SUBSTRATE CAVITY

(71) Applicant: TEXAS INSTRUMENTS INCORPORATED, Dallas, TX (US)

(72) Inventors: Udit Rawat, Allen, TX (US); Brian Goodlin, Plano, TX (US); Bichoy Bahr, Allen, TX (US); Mark L. Jenson, Allen, TX (US)

(21) Appl. No.: 19/255,907

(22) Filed: Jun. 30, 2025

Related U.S. Application Data
(60) Provisional application No. 63/757,576, filed on Feb. 12, 2025.

(51) Int. Cl. B81B 3/00; B81C 1/00

(52) U.S. Cl. CPC B81B 3/0021; B81C 1/0015; B81B 2203/0118; B81B 2203/0315; B81C 2201/0132

(57) ABSTRACT

An apparatus includes a substrate of a first material having opposing first side and second side. In an example, the substrate includes a cavity that that extends from the second side. In an example, the substrate includes a first layer and a second layer of a second material that extends from the first side of the substrate and forms at least parts of opposing side walls of the cavity, in which at least one of: the second material is different from the first material, or the substrate is separated from the first layer and the second layer by a layer of a third material different from the first material. In an example, the apparatus further includes one or more devices on the first side of the substrate.

### RELATED APPLICATIONS

This application claims priority to U.S. provisional patent application No. 63/757,576 titled “Cantilever on Trench Structures” filed Feb. 12, 2025, which is incorporated by reference in its entirety.

### BACKGROUND

Many devices include cavities to support certain functions and/or operations. For example, a transducer may be mounted on a substrate having a cavity to interact with the air (or a fluid) in the cavity. As another example, the cavity of the substrate can be filled an insulator (e.g., air, a dielectric material, etc.) to provide electrical isolation between circuits of different voltage domains in the substrate. In all these examples, the alignment/location of the substrate cavity with respect to other components of the device may affect the device performance.

### BRIEF DESCRIPTION OF DRAWINGS

The examples will be understood more fully from the detailed description given below and from the accompanying drawings, which, however, should not be taken to limit the disclosure to the specific examples, but are for explanation and understanding only.

FIGS. 1A, 1B, 1C, 1D, and 1E are schematics that illustrate devices with cavities, in accordance with various examples.

FIGS. 2A, 2B, and 2C are schematics that illustrate a transducer device having a cantilever beam over a substrate cavity, in accordance with various examples.

FIG. 3 is a schematic that illustrates a transducer device having a cantilever beam in a substrate cavity, in accordance with various examples.

FIG. 4 is a schematic that illustrates a transducer device over a substrate having a cavity defined by a plurality of trench structures, in accordance with various examples.

FIGS. 5A, 5B, 5C, 5D, 5E, and 5F are schematics that illustrate plan views of a transducer device over a substrate having cavities defined by a plurality of trench structures, in accordance with various examples.

FIG. 6 is a flowchart of a method of fabricating a device with a cavity, in accordance with various examples.

FIG. 7A. 7B, 7C, 7D, and 7E are schematics that illustrate cross-sectional views of a device with a cavity at various stages of fabrication, in accordance with various examples.

The same reference numbers are used in the drawings to designate the same (or similar) features.

### SUMMARY

In various embodiments, an apparatus includes a substrate of a first material having opposing first side and second side. In an example, the substrate includes a cavity that that extends from the second side. In an example, the substrate includes a first layer and a second layer of a second material that extends from the first side of the substrate and forms at least parts of opposing side walls of the cavity, in which at least one of: the second material is different from the first material, or the substrate is separated from the first layer and the second layer by a layer of a third material different from the first material. In an example, the apparatus further includes one or more devices on the first side of the substrate.

In various embodiments, a packaged integrated circuit comprises a substrate of a first material having opposing first side and second side, the substrate including a cavity that that extends from the second side; and a first layer and a second layer of a second material that extends from the first side of the substrate and forming at least parts of opposing side walls of the cavity, in which at least one of: the second material is different from the first material, or the substrate is separated from the first layer and the second layer by a layer of a third material different from the first material.

In various embodiments, a method comprises forming a first trench structure and a second trench structure that extend from a first side of a substrate comprising a first material; filling the first and second trench structures with a second material; forming one or more device on the first side of the substrate; and forming a cavity that extend from a second side of the substrate to the first side by removing parts of the substrate between the first and second trench structures, in which the second material in the first and second trench structures form at least parts of opposing side walls of the cavity.

### DETAILED DESCRIPTION

As described above, many devices include cavities to support certain functions and/or operations. For example, a transducer may be mounted on a substrate having a cavity to interact with the air (or a fluid) in the cavity. As another example, the cavity of the substrate can be filled an insulator (e.g., air, a dielectric material, etc.) to provide electrical isolation between circuits of different voltage domains in the substrate. In all these examples, the alignment/location of the substrate cavity with respect to other components of the device may affect the device performance.

One example of such a device is a transducer with a cantilever beam that can move in a substrate cavity, such as an audio device (e.g., a microphone or a speaker), an accelerometer, a stress sensor, etc. In such transducers, one end of the cantilever is on a structure (e.g., a substrate side of the cavity, a post, etc.) forming an anchor point, and the another end of the cantilever beam is a free end that can move in the cavity. The length of the cantilever beam from the anchor point can define the sensitivity and resonant frequency of the transducer device. The distance between the free end of the cantilever beam and a side wall of the cavity, which provides the vent gap, can define the lower 3 dB frequency of the transducer device. Accordingly, variations in the length of the cantilever beam and the vent gap across transducer devices can introduce variations in the sensitivity and the frequency response of the transducer devices.

One source of variations in the length of the cantilever beam across transducer devices can be due to shifts shift in the anchor point(s), which may be caused by misalignment between the cavity and the cantilever beam introduced during fabrication. For example, to fabricate an audio device with a piezoelectric cantilever beam, piezoelectric layers with the electrodes can be formed on a first side (e.g., a front side) of a substrate. The piezoelectric layers can be patterned from the first side to create a vent that also defines the free end of the cantilever beam. A cavity can be created by, for example, an etching operation from a second side (e.g., a back side) of the substrate to provide, for example, a sound port in which the free end of the cantilever beam can move to detect or create sound. Because the patterning of the piezoelectric layers and the etching of the cavity occur from different sides of the substrate, a misalignment between the cavity and the vent may occur. Also, certain etching techniques, such as deep reactive ion etching (DRIE), can form sloped side walls. All of these can introduce uncertainties in the location and the dimension of the cavity, which in turn also introduce uncertainties in the location the anchor point and in the length of the cantilever beam among transducer devices. Such uncertainties, in turn, can affect the sensitivity and frequency response (e.g., resonant frequency and lower 3 dB frequency) of the transducer device, and significantly impacts the performance of the system that uses the cantilever beam.

Accordingly, discussed herein are techniques for defining the location and the dimension of a cavity in a substrate using trench structures. Trench structures, which can include a filler material and/or a liner material different from the substrate, or otherwise have a different etch selectivity from the substrate, can be formed from the first side (e.g., the front side) of the substrate. The device(s) that interact with the cavity (e.g., a piezoelectric cantilever beam) or use the cavity for other purposes (e.g., for electrical isolation) are also formed on the first side of the substrate. The trench structure can be formed around a perimeter of a cavity to be formed. The cavity can then be formed by etching the substrate from the second side (e.g., the back side), and substrate material surrounded by the trench structures can be removed. The etch stops at the filler of the trench structures (e.g., due to the filler having a different etch selectivity, or some of the liner is etched in lieu of the filler), thereby exposing the filler. The exposed filler of the remaining partial trench structures can define the internal walls of the cavity, thus providing a self-aligned cavity.

Such arrangements can improve the precision in setting the location and the dimension of the cavity. Specifically, because the trench structures and the device are formed on the same side of the substrate (e.g., the front side), alignment between the trench structures and the device can be achieved at a high precision. Because the trench structures also define the location and the dimension of the cavity, the alignment between the cavity and the device can also be achieved at a high precision. Meanwhile, the alignment requirement for the etching operation from the other side of the substrate (e.g., the back side) can be relaxed, because the etching stops at the filler of the trench structures. Accordingly, misalignment between the back-side etching operation and the device on the front side has little or no effect on the location and the dimension of the cavity.

The techniques of using trench structures to form a self-aligned cavity can be used to reduce performance uncertainties of various devices that have cavities formed by back-side etching. For example, a transducer device including a piezoelectric cantilever beam (e.g., an audio device, an accelerometer, etc.) can be formed on a first side (e.g., front side) of a substrate having the aforementioned trench structures defining the perimeter and location of a cavity, and the patterning of the piezoelectric layers to form the cantilever beam is aligned with the trench structures. One or more cavities are then formed by etching from a second side (e.g., back side) of the substrate to release the cantilever beam, where the filler of the trench structures can define the internal walls of the cavity, as well as the anchor point and vent gap of the cantilever beam. Because of the improved alignment of the cavities with the cantilever team provided by the trench structures, uncertainty in the properties/performance of the transducer device (e.g., frequency response, sensitivity, etc.) can be reduced.

As another example, a piezoelectric inkjet device can be formed on the front side of the substrate having the aforementioned trench structures defining the perimeters and locations of one or more cavities. The piezoelectric inkjet device can include a reservoir to store ink and a piezoelectric transducer that can exert pressure onto the reservoir to push out ink through the cavities, which act as nozzles. The piezoelectric inkjet device can be aligned with the trench structures. With such arrangements, the locations and dimensions of the nozzles can become more precisely controlled, which can also improve the precision (and reduce the uncertainties) of ink dispense by the inkjet device.

As another example, electronic devices (e.g., transistors, passive devices, etc.) can be formed on the front side of the substrate having the trench structures that define the perimeter and location of a cavity. The fabrication of the electronic devices can be aligned with the trench structures, where electronic devices of different voltage domains are formed on opposing sides of the cavity to be formed. The cavity is then formed by etching the substrate from the back side. The cavity can be filled with a dielectric material (e.g., parylene, oxide, or air) to provide electrical isolation between the electronic devices of different voltage domains. With such arrangements, the location of the cavity with respect to the electronic devices of different voltage domains can be more precisely controlled, which can also improve the electrical isolation provided by the cavity.

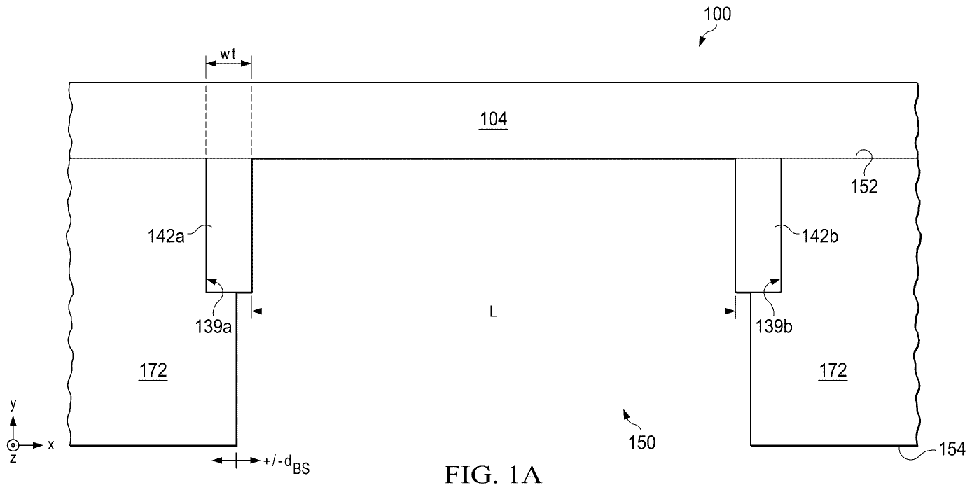

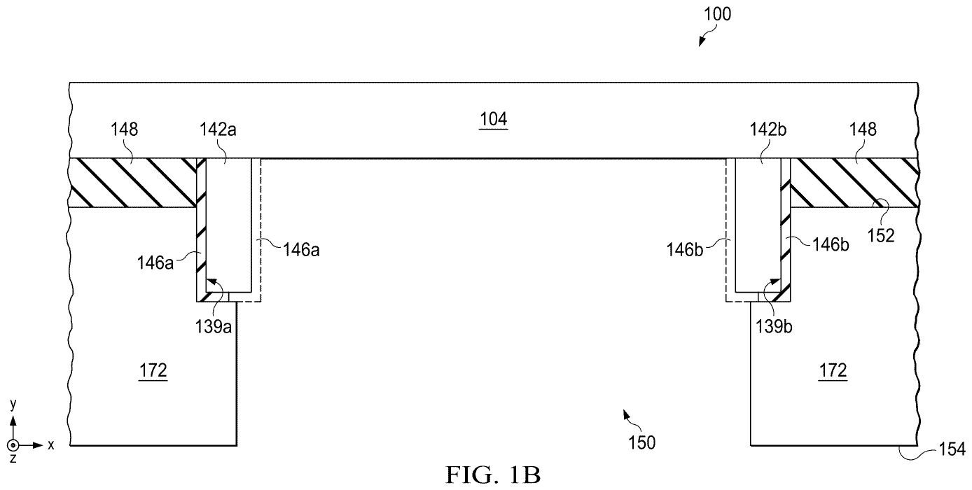

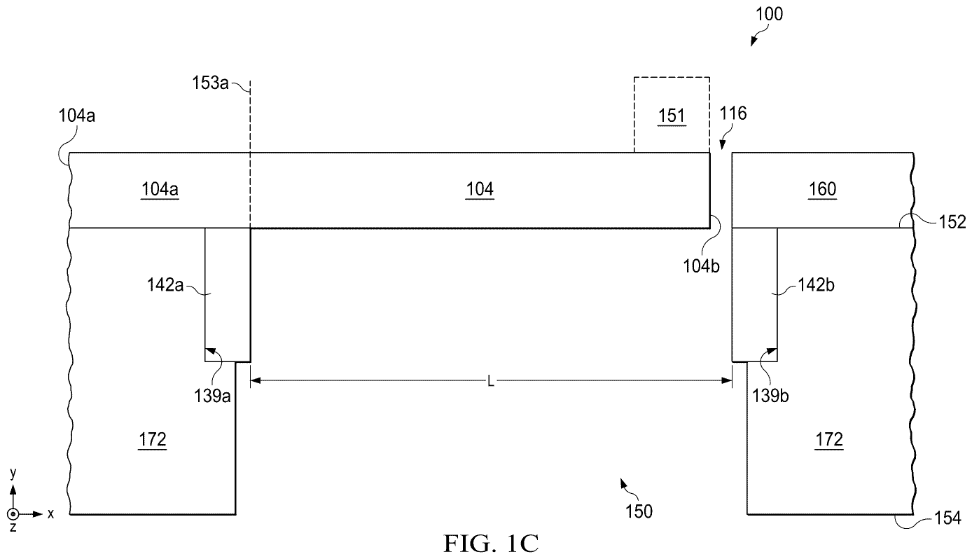

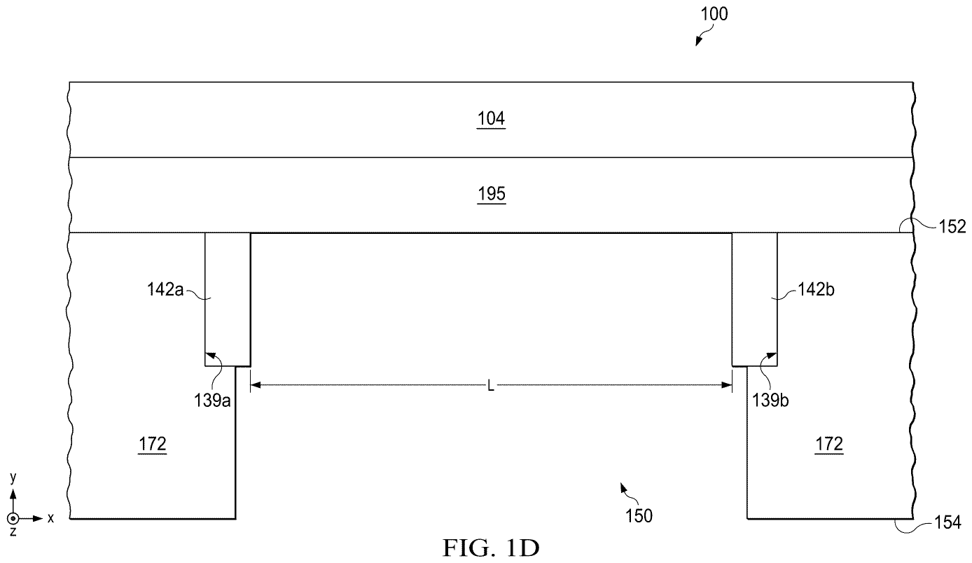

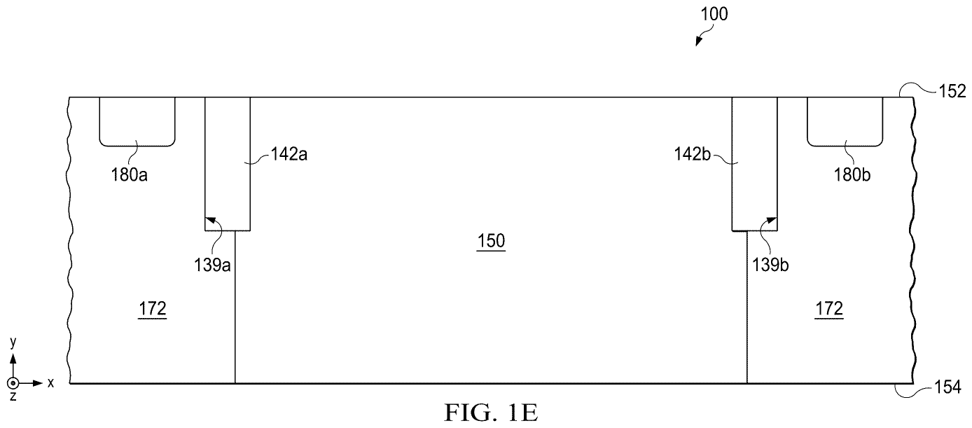

FIG. 1A is a schematic of an apparatus 100 comprising a transducer device 104 that is at least in part on (i) recesses 139a, 139b and (ii) a cavity 150, in accordance with various examples. In an example, transducer device 104 comprises a MEMS (Micro-Electro-Mechanical System) transducer, such as a piezoelectric transducer device, although transducer device 104 may be another type of transducer device. In an example, transducer device 104 comprises a piezoelectric micromachined ultrasonic transducer (PMUT). In an example, transducer device 104 comprises a membranes. In an example, transducer device 104 comprises a piezoelectric film, with one or more electrodes extending on and/or through the piezoelectric film. Example of transducer device are described below in further detail. In yet another example, instead of transducer device 104, another component may extend on recesses 139a, 139b and cavity 150. For example, in a radio frequency (RF) integrated circuit package, an RF inductor (instead of transducer device 104) may extend on recesses 139a, 139b and cavity 150, which may eliminate or at least reduce substrate loss within the inductor. For example, using techniques described herein, portions of substrate 172 below the inductor may be etched to form cavity 150 below the inductor.

Transducer device 104 is on/over a side 152 of a substrate 172. Substrate 172 in an example comprises silicon, although other material (such as a semiconductor material or another type of material) for substrate 172 may also be possible. Apparatus 100, including transducer device 104 and substrate 172, can be part of a packaged integrated circuit. Apparatus 100 comprises a first recess 139a and a second recess 139b that extend from side 152 of substrate 172. Recesses 139a, 139b include filler layers 142a and 142b, respectively. One side of filler layer 142a is covered by substrate 172, and the other side of filler layer 142a is exposed and form an internal wall of cavity 150. Also, one side of filler layer 142b is covered by substrate 172, and the other side of filler layer 142b is exposed and form another internal wall of cavity 150. As illustrated, layers 142a, 142b and substrate 172 define a cavity 150, where layers 142a, 142b form opposing sidewalls of cavity 150. Accordingly, filler layers 142a and 142b together can define a dimension L and a location (e.g., along the x and y axes in FIG. 1A) of cavity 150.

As to be described to below, recesses 139a and 139b are formed by forming trench structures on side 152 of substrate 172, and then part of substrate 172 between the trench structures is removed by an etching operation on a side 154 of substrate 172 opposing side 152, thereby exposing filler layers 142a and 142b and forming recesses 139a and 139b as partial trench structures. The material of layers 142a and 142b are different from the material of substrate 172. For example, layers 142a and 142b are etch selective with respect to substrate 172. Thus, an etchant used in the etching of substrate 172 to form cavity 150 does not etch (or etch substantially more slowly) filler layers 142a and 142b. Accordingly, the filler layers 142a and 142b can provide self-alignment during the etching operation to form cavity 150. The alignment requirement for the etching operation from side 154 of substrate 172 can also be relaxed, because the etching stops at the filler of the trench structures. For example, as shown in FIG. 1A, to ensure that the part of substrate 142 between filler layers 142a and 142b is etched, the allowed uncertainty of etching operation from side 154 of substrate 172 (denoted by d_{BS}) can be no more than half of the width wₜ of filler layer 142a/142b, which is substantially higher than the alignment requirement between the trenches and transducer 104. Accordingly, the alignment requirement for the etching operation from side 154 of substrate 172 can be substantially relaxed with little or no effect on the alignment of cavity 150 with transducer 104.

FIG. 1B is a schematic of another example of apparatus 100 comprising a transducer device 104 on recesses 139a, 139b and cavity 150, where filler layers 142a, 142b are separated from substrate 172 by liner layers 146a and 146b, respectively, in accordance with various examples. Thus, in the example of FIG. 1B, liner layer 146a is on at least some sections of sidewalls of recess 139a, and liner layer 146b is on sidewalls of recess 139b. Apparatus 100 further comprises a layer 148 on at least some sections of side 152 of substrate 172, and can be between transducer device 104 and substrate 172. Recesses 139a, 139b extend or penetrate vertically (e.g., along the z-axis in FIG. 1B) through layer 148 and through substrate 172.

In the example of FIG. 1B, the material of filler layers 142a and 142b can be the same as or different from the material of substrate 172. Also, the material of liner layers 146a and 146b are different from, and etch selective with respect to substrate 172 and layers 142a and 142b. In an example, the material of layer 148 may be same as, or different from the material of layers 146a, 146b.

In some examples, as to be described in details below, both layer 148 and liner layers 146a and 146b can include an oxide material, such as Tetraethyl orthosilicate (TEOS), substrate 172 can include silicon, while filler layers 142a and 142b can also include silicon or a material different from substrate 172. Layer 148 can be on side 152 of substrate 172. Trench structures can be formed in layer 148 and substrate 172, and then transducer device 104 can be formed on/over layer 148 and substrate 172. During the etching operation on side 154 of substrate 172 to form cavity 150, part of substrate 172 between the trench structures can be etched away to form cavity 150, exposing liner layers 146a and 146b, which can be resistant to the etchant that etches substrate 172. In a case where filler layers 142a and 142b are of the same material as substrate 172, liner layers 146a and 146b can protect filler layers 142a and 142b from being etched during the etching of substrate 172. After the etching of substrate 172 is complete, another etching operation can be performed to etch away part of layer 148 below transducer device 104 to expose transducer 104 in cavity 150. In examples where liner layers 146a and 146b have the same material as layer 148, part of liner layers 146a and 146b (represented by the dotted lines contour) can also be etched away when layer 148 is etched, thereby exposing filler layers 142a and 142b to form internal walls of cavity 150. In examples where layer 148 is absent or otherwise is not etched, liner layers 146a and 146b can remain covering filler layers 142a and 142b respectively in cavity 150. In such examples, liner layers 146a and 146b can be exposed in cavity 150 and can define the internal walls of cavity 150.

FIG. 1C is a schematic of an example of apparatus 100 comprising transducer device 104 comprising a cantilever beam (e.g., a cantilever beam including piezoelectric layers and electrodes) on recesses 139a, 139b and cavity 150, in accordance with various examples. The transducer device 104 in FIG. 1C can be an audio device (e.g., a microphone, a speaker, etc.), an accelerometer, a stress sensor, etc. In the example of FIG. 1C, one end 104a of transducer device 104 is attached or anchored to layer 142a at an anchor point 153a defined by a sidewall of cavity 150, which is provided by filler layer 142a (or liner layer 146a if present). Also an opposing end 104b of transducer device 104 is proximal to, but separated from a wall 160, and can move with respect to cavity 150. For example, a vent gap 116 is between an end of transducer device 104 and wall 160. Wall 160 is on/over filler layer 142b and substrate 172 and aligned to filler layer 142b (or liner layer 146b if present). In some examples, as to be described below, transducer device 104 may bend into cavity 150, the vent gap 116 is defined by end 104b of transducer device 104 and filler material 142b (or liner layer 146b if present) in cavity 150. In some examples where transducer device 104 is an accelerometer or a stress sensor, a load mass 151 may be on end 140b of transducer device 104.

As explained above, both transducer device 104 and trench structures (which lead to recesses 139a and 139b and filler layers 142a and 142b) are formed on side 152 of substrate 172, which allows precise alignment of anchor point 153a and vent gap 116 with respect to filler layers 142a and 142b. The exposed filler layers 142a and 142b (or liner layers 146a and 146b if present), in turn, can define the location and dimension of cavity 150 during the etching of substrate 172 on side 154. This allows precise control of the locations of anchor point 153a and vent gap 116 as well as the length L of the cantilever beam and reduces the uncertainty in the frequency response and sensitivity of transducer device 104.

FIG. 1D is a schematic of an example of apparatus 100 comprising transducer device 104 and a reservoir 195 that are at least in part on (i) recesses 139a, 139b and (ii) a cavity 150, in accordance with various examples. In some examples, transduce device 104, reservoir 195, and cavity 150 of FIG. 1D can be part of a piezoelectric inkjet device. Specifically, transducer device 104 comprises a piezoelectric actuator that converts electrical energy into mechanical actuator force, which exerts force and corresponding movement on reservoir 195, causing a fluid in reservoir 195 (e.g., ink) to be dispensed from reservoir 195 through cavity 150, where cavity 150 forms a nozzle. The location and dimension of cavity 150 (and nozzle) are defined by filler layers 142a and 142b (or liner layers 146a and 146b if present). Transducer device 104, reservoir 195, and trench structures (which lead to recesses 139a and 139b and filler layers 142a and 142b) are formed on side 152 of substrate 172, which allows precise alignment of transducer device 104 and reservoir 195 with cavity 150 formed by etching on side 154 of substrate 172. With such arrangements, the location and the dimension (L) of the nozzle can become more precisely controlled, which can also improve the precision (and reduce the uncertainties) of ink dispensation by the inkjet device.

FIG. 1E is a schematic of an example of apparatus 100 comprising cavity 150 for electrical isolation, in accordance with various examples. In some examples, apparatus 100 includes an electronic device 180a and an electronic device 180b (e.g., transistor devices, passive devices, etc.) on side 152 of substrate 172. Electronic devices 180a and 180b can be of different voltage domains and are separated by cavity 150, which can be filled with a dielectric material (e.g., parylene, oxide, or air) to provide electrical isolation between electronic devices 180a and 180b. The location and dimension of cavity 150 are defined by filler layers 142a and 142b (or liner layers 146a and 146b if present). Because devices 180a and 180b and trench structures (which lead to recesses 139a and 139b and filler layers 142a and 142b) are formed on side 152 of substrate 172, the trench structures (and filler layers 142a and 142b) allow precise alignment of electronic devices 180a and 180b with cavity 150 formed by etching from side 154 of substrate 172. With such arrangements, the location and the dimension of cavity 150 can become more precisely controlled to ensure that cavity 150 is between electronic devices 180a and 180b to provide electrical isolation.

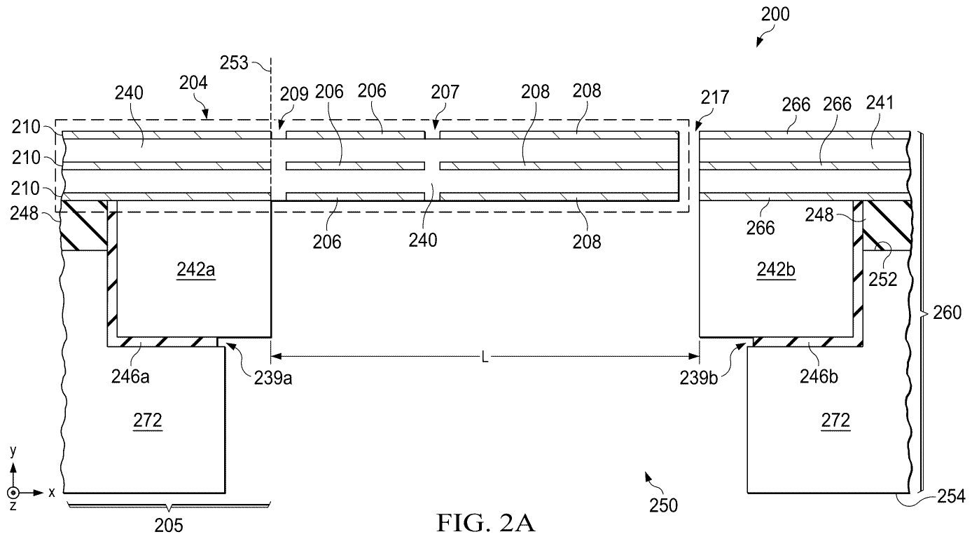

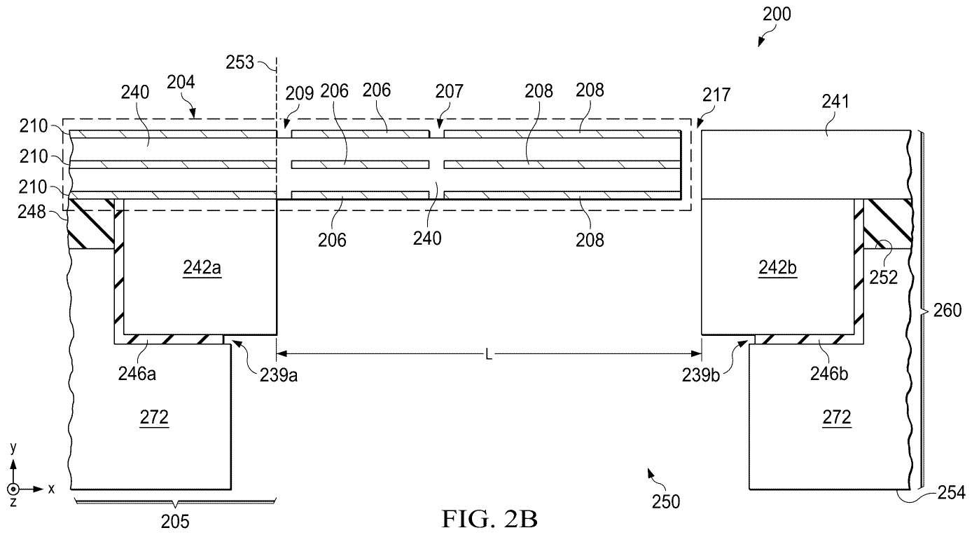

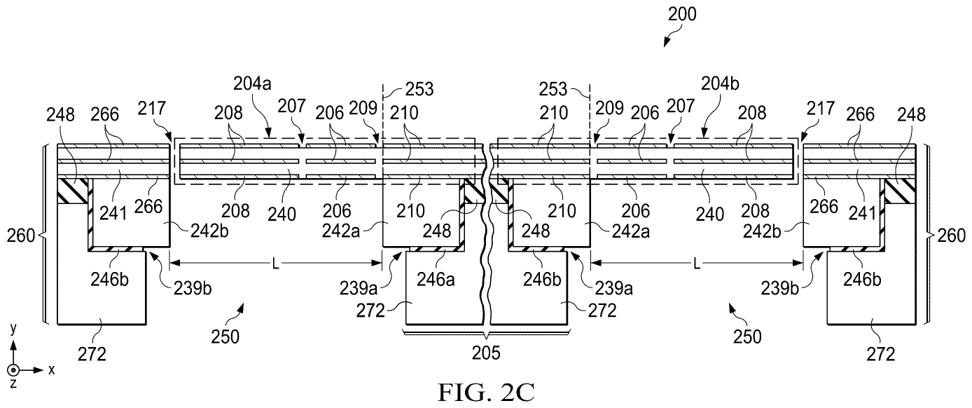

FIG. 2A is a schematic of an apparatus 200 comprising a transducer device 204 including a cantilever beam, wherein transducer device 204 is at least in part on (i) recesses 239a, 239b and (ii) a cavity 250, in accordance with various examples. Transducer 204 is formed on a side 252 (e.g., front side) of substrate 272 (e.g., a silicon substrate), while cavity 250 is formed by etching from a side 254 (e.g., back side) of substrate 272. In some examples, transducer 204 can be separated from side 252 of substrate 272 by a layer 248, which can be an example of layer 148 of FIG. 1B. Apparatus 200 can be an example of apparatus 100 of FIGS. 1A and 1C. Recesses 239a and 239b can be examples of recesses 139a and 139b of FIGS. 1A-1E, and cavity 250 can be an example of cavity 150 of FIGS. 1A-1E. Apparatus 200 includes filler layers 242a and 242b in recesses 139a and 139b, respectively. In the examples show in FIGS. 2A-2C, filler layers 242a and 242b are exposed in cavity 250. Apparatus 200 also includes liner layers 246a and 246b that separate filler layers 242a and 242b from substrate 272. Filler layers 242a and 242b can be examples of filler layers 142a and 142b of FIGS. 1A-1E, and liner layers 246a and 246b can be examples of liner layers 146a and 146b.

In an example, transducer device 204 comprises piezoelectric layer 240 and stacks of electrodes. In some examples, piezoelectric layer 240 can include a top piezoelectric film and a bottom piezoelectric film forming a bimorph, where the top piezoelectric film is between a top electrode and a middle electrode, and the bottom piezoelectric film is between the middle electrode and the bottom electrode. Transducer device 204 can include a cantilever beam including part of piezoelectric layer 240 and electrodes that extends from anchor 253. In examples where transducer device 204 operates as a sensor (e.g., an audio device, an accelerometer, etc.), an external force can cause the cantilever beam to bend and generate stress in the top and bottom piezoelectric films. The stress can generate electric fields in the top and bottom piezoelectric films, and the electric fields can be sensed through the top, middle, and bottom electrodes. In examples where transducer device 204 operates as an actuator (e.g., a speaker), the top, middle, and bottom electrodes can receive voltage signals to create electric fields across the top and bottom piezoelectric films. The electric fields can create stress and cause the cantilever to bend.

In an example, each stack of electrodes within piezoelectric layer 240 is separated from an adjacent stack of electrodes by a discontinuity or gap. For example, stack of inner electrodes 206 is separated from stack of central electrodes 210 by a gap 209, and stack of inner electrodes 206 is separated from stack of outer electrodes 208 by a gap 207. Thus, for example, an electrode of stack of inner electrodes 206 is separated from a corresponding electrode of stack of central electrodes 210 by gap 209. Although not illustrated in FIG. 2A, an electrode within a stack of electrodes may be conductively coupled to another electrode of an adjacent stack by a wire bound or by other conductive arrangement. Although three separate stacks of electrodes are illustrated in FIG. 2A, transducer device 204 may include fewer or higher number of stacks of electrodes.

In an example, stack of outer electrodes 208 may not play a functional role in sensing or creating electric fields. Stack of outer electrodes 208 may be present for purposes of providing a planar upper surface above piezoelectric layer 240, such that an upper surface of stack of inner electrodes 206 and an upper surface of stack of outer electrodes 208 are coplanar. In an example, stack of outer electrodes 208 may be absent from apparatus 200. Functionality of inner and central stack of electrodes 206, 210 are described below in further detail.

In an example, a section of piezoelectric layer 240 forms a cantilever beam. For example, one end of piezoelectric layer 240 is attached or anchored to a central post 205, while an opposing end is adjacent to, but separate from, a wall 260. For example, a vent gap 217 separates the piezoelectric layer 240 from wall 260.

In an example, wall 260 comprises a layer 241. In one example, layer 241 may comprise piezoelectric material. In another example, layer 241 may comprise non-piezoelectric material. For example, even if layer 241 is piezoelectric material, piezoelectric properties of layer 241 may not be functionally used in apparatus 200. In an example, layer 241 may comprise piezoelectric material, e.g., to make the fabrication process of apparatus 200 relatively easier (e.g., such that layers 240 and 241 may be deposited during a same deposition process). However, in another example, different deposition processes may be employed to form layers 240 and 241, such that layer 241 may have different material relative to layer 240, and in such an example, layer 241 may comprise non-piezoelectric material.

As illustrated in FIG. 2A, layer 241 may comprise a stack of wall electrodes 266. In another example, wall electrodes 266 may be absent from apparatus 100. In an example, stack of wall electrodes 266 may not play a functional role in conducting current. Stack of wall electrodes 266 may be present for purposes of providing a planar upper surface above layer 241 with respect to upper surfaces of electrodes of layer 240, such that an upper surface of stack of wall electrodes 266 is coplanar with upper surfaces of stacks of inner, central, and outer electrodes 206, 208, 210. In an example, stack of wall electrodes 266 may be absent from apparatus 200.

As illustrated, layers 240 and 241, along with various stacks of electrodes therewithin, form transducer device 204. Transducer device 204 can be part of a microphone or a speaker. When operating as a microphone, sound waves cause the cantilever beam portion of piezoelectric layer 240 to vibrate, and/or to generate stress within the cantilever beam portion of piezoelectric layer 240. For example, when sound waves hit apparatus 100, air pressure resultant from the sound waves cannot substantially escape from vent gap 217 (e.g., as vent gap 217 may be small enough, such as in the range of 0.5 microns to 10 microns). Upon interaction with sound waves, a first portion of piezoelectric layer 240 (which is at the free end of piezoelectric layer 240 and which has stack of outer electrodes 208 embedded therewithin) develops motion which is perpendicular to the plane of piezoelectric layer 240 (e.g., motion is in a z-direction while the plane of piezoelectric layer 240 is in the x-y direction). The motion is converted into electrical signal(s) on a second portion of piezoelectric layer 240 that has inner electrodes 206, causing generation of electricity within inner electrodes 206. In an example, gap 207 provides a medium for transduction of motion from the first portion to electrical signal on inner electrodes 206 with the second portion. Thus, sound waves causes stress on piezoelectric layer 240, and the stress may be relatively more at the area of piezoelectric layer 240 where stack of inner electrodes 206 are present. The stress of the piezoelectric layer 240 creates electric fields within stack of inner electrodes 206, and the electric fields can be sensed (e.g., as voltages) via central electrodes 210. A sensing circuit measures the voltages, thereby estimating a magnitude of the sound wave. Configuration of piezoelectric layer 240 and the electrodes embedded and/or on piezoelectric layer 240 are described in further detail in co-pending U.S. patent application Ser. No. 18/522,145, entitled “PIEZOELECTRIC TRANSDUCER HAVING TAPERED CANTILEVER,” filed on Nov. 28, 2023, which is incorporated herein in its entirety.

Piezoelectric layer 240 has the cantilever beam that is above cavity 250, and a fixed (or restrained) portion that is above central post 205. Thus, the fixed portion of piezoelectric layer 240 is anchored to central post 205. An anchor point 253 defines a point (or plane) from which the cantilever portion of piezoelectric layer 240 starts. An edge of layer 242a defines anchor point 253. A length L of cantilever portion of piezoelectric layer 240 is defined between anchor point 253 and free end of piezoelectric layer 240. In an example, length L dictates characteristics of transducer device 204. Also, vent gap 217 can be aligned with filler layer 242b.

As described herein, in an example, anchor point 253 is self-aligned to an edge of filler layer 242a, which can be part of a trench structure formed on side 252. Thus, once the position of the edge of layer 242a is fixed while forming the trench structure from side 252 of substrate 272, anchor point 253 is also self-aligned to the edge of layer 242a. Because the trench structure and transducer 204 are both formed on the same side 252 of substrate 272, alignment between transducer 204 (e.g., vent gap 217) and the trench structures can be achieved at a high precision more easily. Also, cavity 250 is formed by etching substrate 272 from side 254 of apparatus 200, but the etching stops at filler layers 242a and 242b. Thus, a misalignment in the etching from the side 254 does not lead to shifting of anchor point 253, thereby fixing or self-aligning anchor point 253, and the location and the dimension of cavity 250 can be defined by filler layers 242a and 242b. The length of the cantilever beam, as well as the size of vent gap 217, can also be more precisely controlled by filler layers 242a and 242b. Part of substrate 272, recess 239a, and filler layer 242a (and liner layer 246a if present) on a first side of cavity 250 can form central post 205, and part of substrate 272, recess 239b, and filler layer 242b (and liner layer 246b if present) on a second side of cavity 250 can form wall 260.

In an example, material of filler layers 242a, 242b are different from material of liner layer 246a, 246b. For example, layers 242a, 242b are etch selective with respect to layer 246a, 246b and/or layer 248. Thus, an etchant during an etch process may substantially etch material of layers 246a, 246b and/or layer 248, without substantially etching material of layers 242a, 242b. Such etch selectivity facilitates in fabrication of apparatus 200 and self-alignment of anchor point 253, as described below in further detail.

In an example, material of filler layers 246a, 246b are different from material of substrate 272. For example, filler layers 246a, 246b can have a different etch selectivity from substrate 272 for a particular etchant. Thus, an etchant may substantially etch material of substrate 272, without substantially etching material of layers 246a, 246b. Similarly, another etchant may substantially etch material of layers 246a, 246b, without substantially etching material of substrate 272.

In an example, material of layer 248 is different from material of substrate 272. For example, layer 248 has a different etch selectivity from substrate 272 for a particular etchant. Thus, an etchant may substantially etch material of substrate 272, without substantially etching material of layer 248. Similarly, another etchant may substantially etch material of layer 248, without substantially etching material of substrate 272.

The above-described etch selectivity between various material facilitates in self-alignment of anchor point 253, as described below in further detail.

In an example, material of layer 248 may be same as, or different from material of layers 246a, 246b. In an example, material of substrate 272 may be same as, or different from material of layers 242a, 242b.

In an example, substrate 272 comprises silicon, although other material (such as a semiconductor material or another type of material) for substrate 272 may also be possible. In an example, layer 248 comprises Tetraethyl orthosilicate (TEOS), an oxide material, or another material. In an example, filler layers 242a, 242b comprises with a material compatible with front end processing, such as spin-on-glass (SOG), silicon (such as polysilicon), metal, silicon oxide, silicon nitride.

In an example, liner layers 246a, 246b (which are on sidewalls of respective recesses 239a, 239b) may include an appropriate oxide layer, such as aluminum oxide. In an example, liner layers 246a, 246b protects filler layers 242a, 242b during an etch process to etch substrate 272 from back side, as described below in further detail. In examples where filler layers 242a and 242b have a different material from substrate 272, liner layers 246a and 246b can be omitted.

FIG. 2B is a schematic of another example of apparatus 200 comprising a transducer device 204 that is at least in part on (i) recesses 239a, 239b and (ii) a cavity 250, in accordance with various examples. In the example of FIG. 2B, no wall electrodes are within or on layer 241.

FIG. 2C is a schematic of another example of apparatus 200 comprising a plurality of transducer devices 204a, 204b, in accordance with various examples. Each of transducer devices 204a, 204b is similar to transducer device 204 of FIG. 2A. In FIG. 2C, transducer devices 204a, 204b are interconnected through central post 205. Thus, central post 205 is at a center of apparatus 200C, with two transducer devices 204a, 204b extending on two sides of central post 205. In an example, multiple such transducer devices 204a, 204b may extend on multiple sides of central post 205, as described below in further detail. Note that various components in transducer devices 204a, 204b are labelled using similar labels.

Because center post 205 in at a center of such a plurality of transducer devices, post 205 is referred to as a “center” post. For similar reasons, stack of electrodes 210 are referred to as stack of “center” electrodes, and stack of electrodes 208 are referred to as stack of “outer” electrodes.

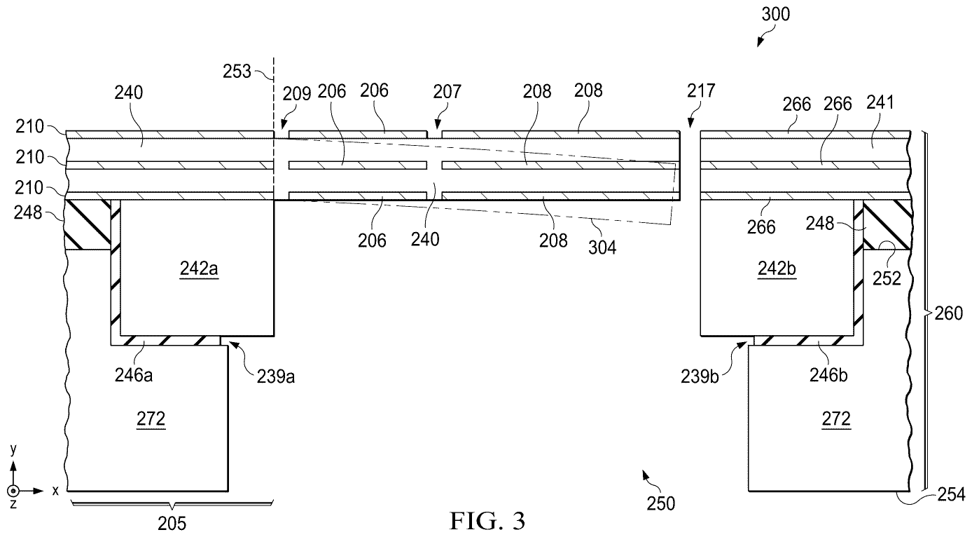

FIG. 3 is a schematic of an apparatus 200 comprising a transducer device 204 that is at least in part on (i) recesses 239a, 239b and (ii) a cavity 250, wherein at least a section of transducer device 204 bends down into cavity 250 (e.g., at about half of the height of filler layer 242b along the z-axis) at a native or nominal position (e.g., without an external stress or an external actuation signal), as illustrated by dotted lines 304 in FIG. 3. Apparatus 300 of FIG. 3 is an example of apparatus 200 of FIG. 2A. With such arrangements, the free end of transducer 204 (end 211) can be opposing filler layer 242b (or liner layer 246b if present), and vent gap 217 is self-aligned with filler layer 242b/liner layer 246 b. Such arrangements can provide more precise control over vent gap 217 and reduce uncertainties in the lower 3 dB frequency of transducer device 204.

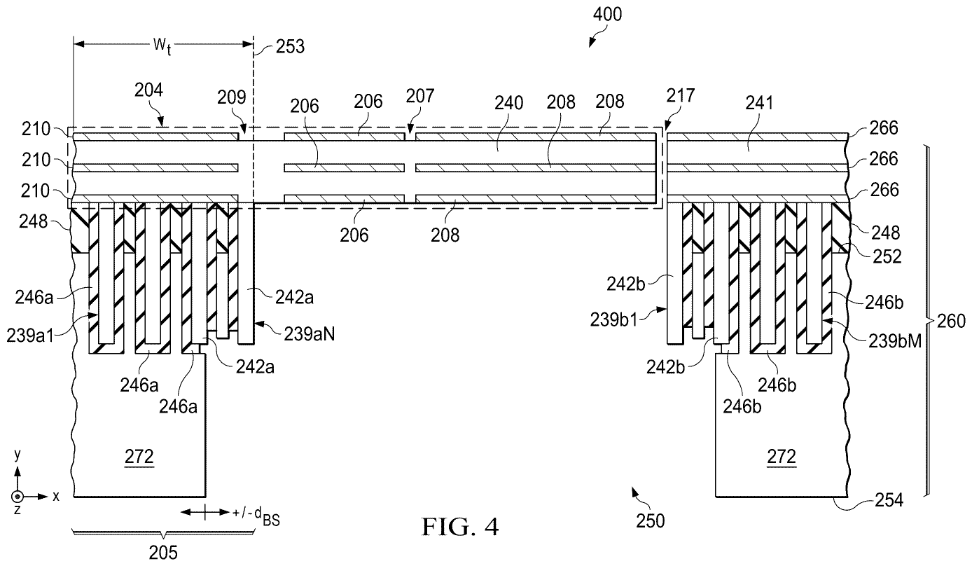

FIG. 4 is a schematic of an apparatus 400 comprising a transducer device 204 having a beam including a fixed portion and a cantilever beam on two sides of anchor 253. Apparatus 400 can be an example of apparatuses 100, 200, and 300 as described herein. The fixed portion including central electrodes 210 is over a plurality of trench structures and partial trench structures/recesses in layer 248 and substrate 272, including trench structure 239a1 and partial trench structure/recess 239aN, that are part of central post 205. Also, wall 260 also includes a plurality of trench structures and partial trench structures/recesses in layer 248 and substrate 272, including trench structure 239bM and partial trench structure/recess 239b1. The trench structures and partial trench structures are formed on side 252 of substrate 272. The cantilever portion is also on side 252 of substrate 272. A cavity 250 is formed below the cantilever portion by etching from side 254 (e.g., back side) of substrate 272 to form cavity 250.

Apparatus 400 includes liner layers (e.g., liner layers 246a, 246b) covering the sidewalls and bottom of each trench structure, or covering at least parts of the partial trench structures. Also, apparatus 400 includes a filler layer (e.g., filler layer 242a, 242b) in each trench structure or exposed in the partial trenches. The exposed filler layer in the inner most partial trenches (e.g., partial trenches 239aN and 239b1) can define the location and dimension of cavity 250, as well as the location of anchor 253. The partial trenches are formed by etching away part of substrate 272 from side 254 (e.g., back side) of substrate 272 to form cavity 250. Part of liner layers 246a, 246b in the partial trenches can also be etched away when the portion of layer 248 below the cantilever portion is etched to release the cantilever portion.

In the example of FIG. 4, each trench structure can have a narrower width (e.g., along the x/y axes) compared with a single trench structure from which recesses 239a/239b of FIGS. 2A-2C is formed. The narrower width can facilitate deposition of the filler material in the trench structures, while the total width of the trench and partial structures (wₜ in FIG. 4) can remain large to relax the allowed uncertainty of the etching operation on side 254 (d_{BS} in FIG. 4) to form cavity 250. Also, due to the higher aspect ratio, the etching of substrate 272 between the liner layers of adjacent trench structures in central post 205 and wall 260 can occur at a much lower rate than the etching of substrate 272 between the innermost trench structures (to form cavity 250). The remaining substrate 272 between the liner layers adjacent trench structures can improve the structural strength of central post 205 and wall 260.

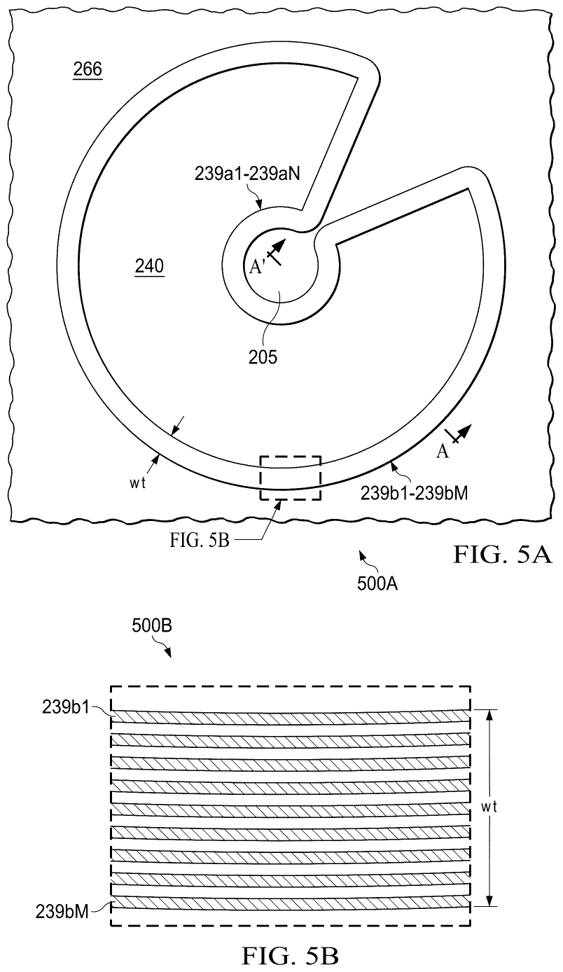

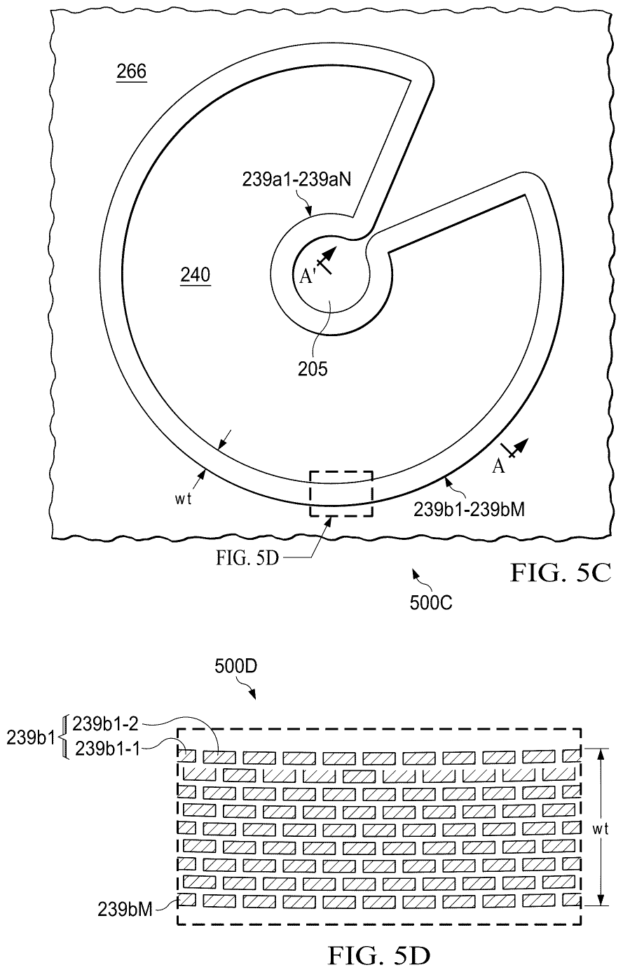

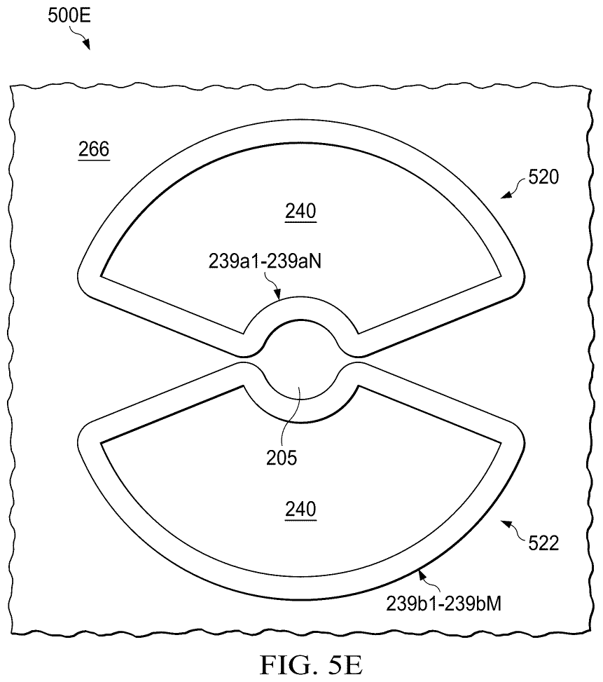

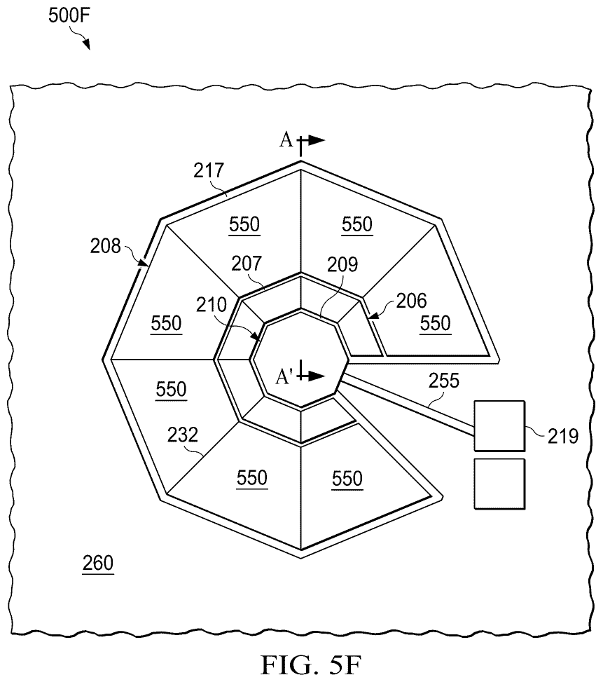

FIGS. 5A, 5B, 5C, 5D, and 5E illustrate plan views of an apparatus 500 comprising a transducer device, in which a transducer device at least partially wraps around a central post 205, in accordance with various examples. Apparatus 500 of FIGS. 5A and 5B can be an example of apparatus 100, 200, 300, and 400 as described herein. FIG. 5B is a magnified view of a section of the apparatus (illustrated in a dotted rectangular) illustrated in FIG. 5A. For example, a cross-sectional view of any of the apparatuses 100, 200, 300, and 400 may be along line A-A′ of FIG. 5A. Apparatus 500 includes central post 205, and piezoelectric layer 240 that wraps at least partially around central post 205. In FIGS. 5A and 5B, each of trench structures, including trench structures 239b1, ..., 239bM, can include a continuous trench structure that wraps around a periphery of cavity 250. The total widths of the trench structure is denoted by wₜ. FIG. 5D is a magnified view of a section of the apparatus (illustrated in a dotted rectangular) illustrated in FIG. 5C. Also, in FIGS. 5C and 5D, each of trench structure can include discrete segments. For example, trench structure 239b1 can include segments 239b1-1, 239b1-2, etc. Such arrangements allows the fabrication of the trench structures to be more compatible with fabrication of other devices, such as transistors, on the substrate. In some examples, the trench structures can also have a non-continuous or a staggered geometry to create high aspect ratio geometries in the substrate. Substrate portions having such high aspect ratio geometries can be resistant to etching, and can largely remain between the neighboring segments of the trench structure after the etching operation to form cavity 250. Such arrangements can improve the structural integrity of the trench structure.

FIG. 5E illustrates a plan view of another example of apparatus 500. As shown in FIG. 5E, apparatus 500 can include a transducer device that at least partially around a central post 205, and the transducer device is segmented in two sections 520 and 522 wrapped at least partially around central post 205. Each of sections 520, 522 has a curved or circular shaped inner edge adjacent central post 205, a curved or circular shaped outer edge adjacent wall 260, and two straight edges also adjacent wall 260. Each of sections 520, 522 has corresponding piezoelectric layer including a cantilever beam and electrodes. The two sections are separated by the wall and the central post.

FIG. 5F illustrates a plan view of another example of apparatus 500D comprising a transducer device having a plurality of segments 550, in accordance with various examples. Each segment is discontinuous with respect to an adjacent segment via a discontinuity 232. Each segments 550 comprises a corresponding piezoelectric layer 240, and stacks of inner, outer, and central electrodes 206, 208, 210, as described above with respect to FIG. 2A. In the plan view of FIG. 5F, the uppermost electrode of each stack are illustrated. Signals are transmitted to and from apparatus 500D via an interconnect 255 and a conductive pad 219. Configuration of flap portions or segments 550 and various components are described in further detail in co-pending U.S. patent application Ser. No. 18/522,145, entitled “PIEZOELECTRIC TRANSDUCER HAVING TAPERED CANTILEVER,” filed on Nov. 28, 2023, which is incorporated herein in its entirety.

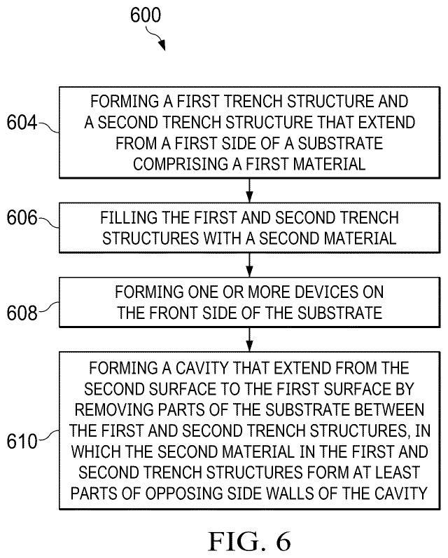

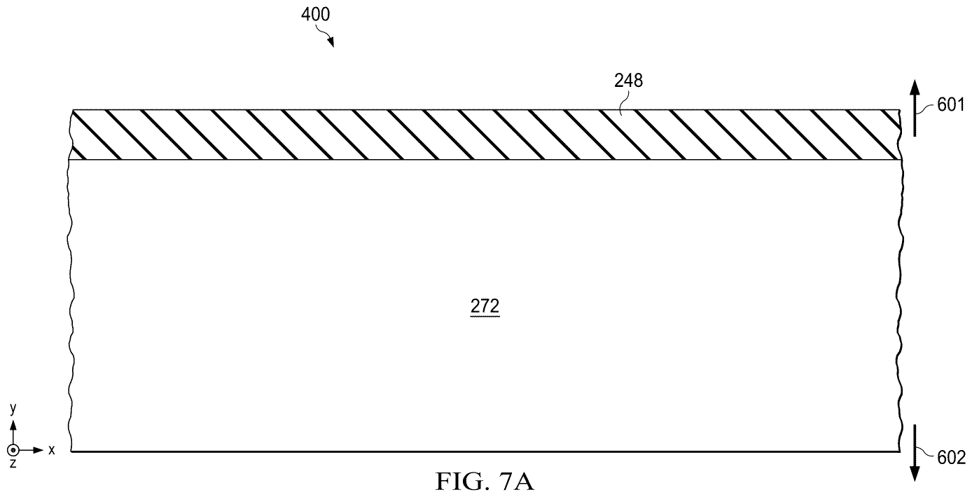

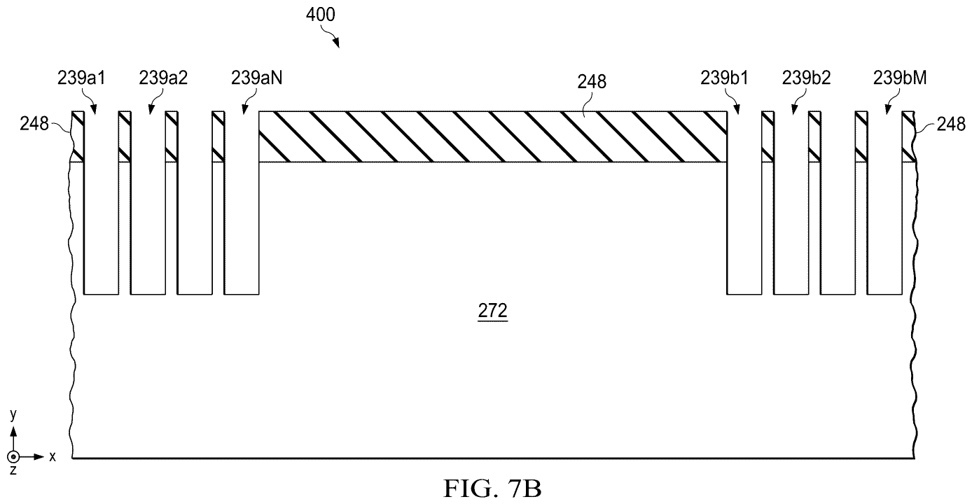

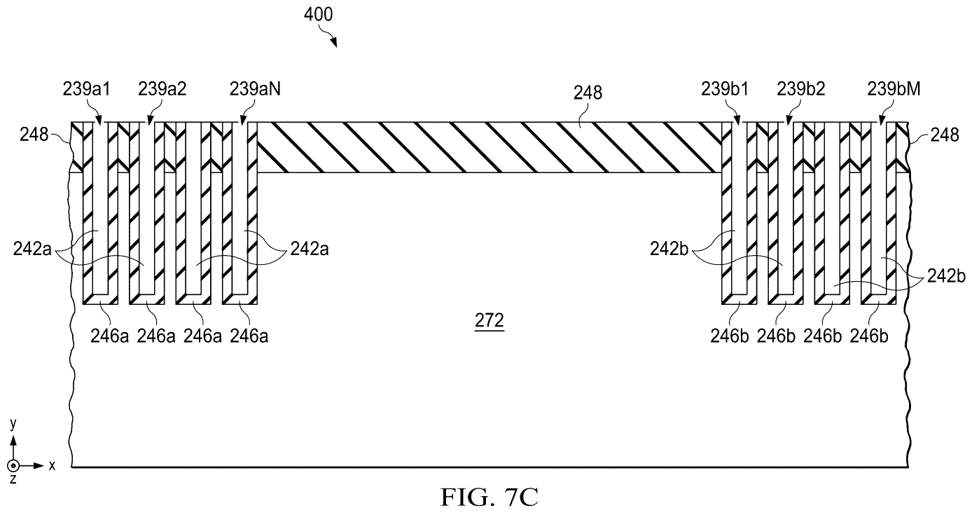

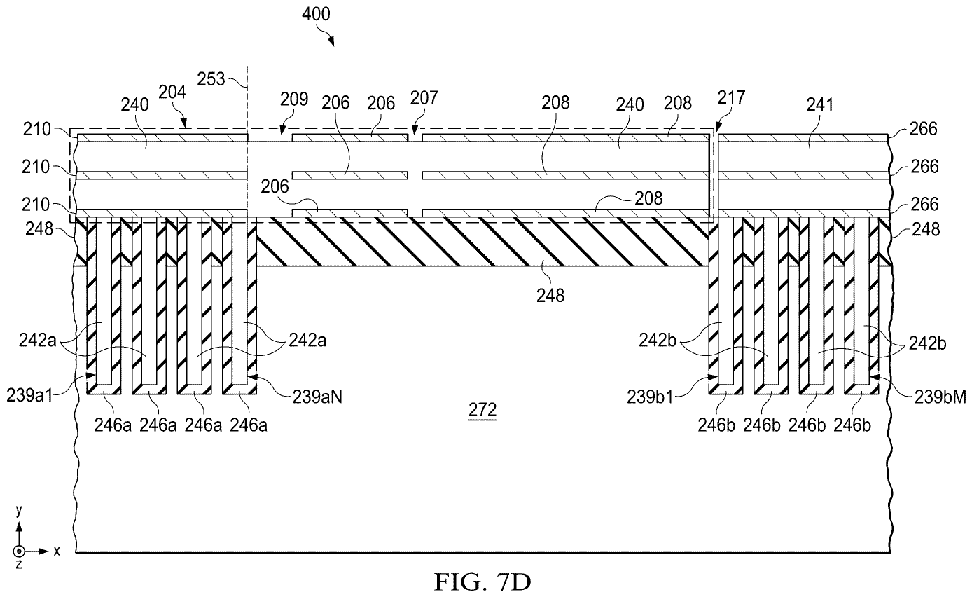

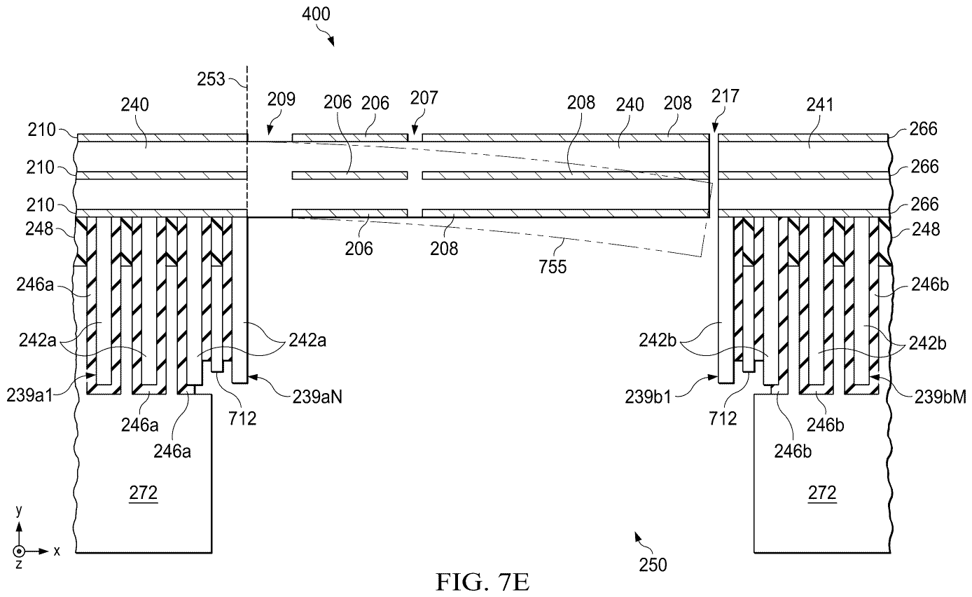

FIG. 6 is a flowchart of a method 600 of fabricating an apparatus comprising a transducer device 204 that is at least in part on a plurality of trench structures and a cavity, in accordance with various examples. Various blocks of the flowchart of method 600 are shown in a particular order. The order can be modified. For example, some blocks can be performed before others and some blocks may be performed in parallel. FIG. 7A. 7B, 7C, 7D, and 7E illustrate cross-sectional views of an apparatus 400 at various stages of fabrication of apparatus 400, in accordance with various examples. For example, FIGS. 7A-7E illustrate various stages of method 600 of FIG. 6.

Although method 600 and FIGS. 7A-7E are directed towards fabrication of an apparatus comprising a plurality of trench structures and partial trench structures/recesses within the central post and a plurality of trench structures and partial trench structures/recesses within the wall (e.g., as described above with respect to at least FIG. 4), the method can be easily modified to fabricate a device having a single partial trench structure/recess within the central post and/or a single partial trench structure/recess within the wall portion, e.g., as described above with respect to at least FIGS. 1A-3.

In operation 604, a first trench structure and a second trench structure that extend from a first side (e.g., a front side) of a substrate comprising a first material are formed.

Referring to FIG. 7A and FIG. 7B, layer 248 is formed on an upper surface of substrate 272, as illustrated in FIG. 7A. A side adjacent to an upper surface of substrate 272 is referred to as a front side 601 of apparatus 400, as illustrated in FIG. 7A. An opposing side adjacent to a lower surface of substrate 272 is referred to as a back side 602 of apparatus 400. Layer 248 may be deposited from front side 601 on substrate 272 using an appropriate deposition technique, such as chemical vapor deposition (CVD), atomic layer deposition (ALD), physical vapor deposition (PVD), sputtering, evaporation, molecular beam epitaxy (MBE), plasma-enhanced CVD (PECVD), low pressure CVD (LPCVD), metal organic CVD (MOCVD), or another technique. As described above, in an example, substrate 272 comprises silicon or another semiconductor material or another type of substrate material, and layer 248 comprises TEOS, an oxide material, or another material that is etch selective with respect to material of substrate 272. In some examples, layer 248 is not deposited.

Also, referring to FIG. 7B, from front side 601, a first plurality of trench structures 239a1, ..., 239aN and a second plurality of trench structures 239b1, ..., 239bM extending through layer 248 and substrate 272 are formed by etching through layer 248 (if present) and substrate 272 using any appropriate technique, such as deep reactive ion etching (DRIE), or similar techniques to create deep contacts for buried layers.

Referring back to FIG. 6, in operation 606, the first and second trenches are filled with a second material.

Referring to FIG. 7C, each trench structure can be filled with a filler layer 242. Filler layer 242 can have the same material or a different material from substrate 272. In some examples, filler layer 242 can be a material that is compatible with fabrication of other devices (e.g., complementary metal oxide semiconductor (CMOS) front side processing, such as spin-on-glass (SOG), silicon, metal, any silicon-oxide or silicon-nitride compounds that can deposited with good step-coverage and fast gap filling. In a case where layer 248 is present, filler layer 242 can be a different material or otherwise has a different etch selectivity (with respect to a particular etchant) from layer 248.

In some examples, each trench structure also includes liner layer 246 between filler layer 242 and the trench structure internal walls and bottom surfaces. Liner layer 246 can include an oxide material, such as LPCVD oxide, thermal oxide, aluminum oxide (Al2O3), to provide better resistance to the subsequent etch process for forming cavity 250 and to better step coverage. Liner layer 246 and trench filler layer 242 may be deposited using, for example, CVD, ALD, PVD, sputtering, evaporation, MBE, PECVD, LPCVD, MOCVD, or another deposition technique.

Referring back to FIG. 6, in operation 608, one or more devices are formed on the front side of the substrate.

Referring to FIG. 7D, in some examples, a transducer device 204 is formed on layer 248 and the trench structures, and on front side 601 of substrate 272. As described above, transducer device 204 comprises piezoelectric layer 240 with various stacks of electrodes, and layer 241 with wall electrodes 266, with a vent gap 217 between piezoelectric layer 240 and layer 241. The patterning of the piezoelectric layer to form vent gap 217, as well as the patterning of the electrodes, can be aligned with the trench structures. Since both the trench structures and the piezoelectric layer are formed on front side 601, high precision alignment can be easily achieved.

In some examples, while depositing piezoelectric layer 240 of transducer device 204, process parameters are controlled such that the cantilever beam of piezoelectric layer 240 (after being released) is in cavity 250 at its nominal position, as to be described below.

Other devices can also be formed. For example, referring to FIG. 1D, reservoir 195 can be formed over the trench structures. Also, referring to FIG. 1E, first and second devices (e.g., transistors, passive devices, etc.) of different voltage domains can be formed in substrate 272, where the first and second trench structures can be between the first and second devices.

Referring back to FIG. 6, in operation 610, a cavity that extends from a second side (e.g., back side) of the substrate to the first side of the substrate is formed by removing parts of the substrate between the first and second trench structures, in which the second material in the first and second trench structures form at least parts of opposing side walls of the cavity.

Referring to FIG. 7E, from back side 602 of substrate 272, at least a portion of substrate 272 is etched to form cavity 250, as illustrated in FIG. 7E. The etch process may be performed by placing a patterned mask on a lower or back side of substrate 272, and etching substrate 272 through an opening within the mask. Due to misalignment in mask placement, cavity 250 may not be perfectly aligned with respect to transducer device 204. However, as described herein, due to the self-alignment of anchor point 253 to an edge of recess 239aN and filler layer 242a within recess 239aN, such misalignment during formation of cavity 250 from back side does not shift anchor point 253.

In an example, the etch process may be selective to the material of substrate 272, such that the etch process etches substrate 272, without substantially etching layers 248, 239a1, ..., 239aN, 239 b1, ..., 239bN. Thus, in FIG. 7E, cavity 250 is formed within substrate 272, and not within layers 248, 239 a1, ..., 239 aN, 239 b1, ..., 239bN.

In an example, the back side etch may be an anisotropic etch process. In an example, the back side etch may use a plasma-based etch process, such as a deep reactive ion etching (DRIE) process. Other type of dry etch processes (such as Bosch etch) may also be used. In another example, wet etch using an appropriate etchant tetramethylammonium hydroxide (TMAH) may also be used. During the etching of substrate 272, part of the liner layer in some of the trench structures (e.g., 239aN and 239b1) may also be removed, thereby exposing the filler material 242a and 242b in those trench structures. The exposed filler materials can form part of the opposing side walls of the cavity and can define, for example, the location and dimension of the cavity, the anchor point, and the vent gap distance. Part of substrate 272 between adjacent trench structures can also be etched, but the etching can be much slower due to the high aspect ratio, therefore much of substrate 272 between adjacent trench structures can remain, which can improve the structural integrity of the trench structures.

Also, in examples where layer 248 is present, portions of layer 248 that are exposed through the cavity 250 can also be etched in another etching process from the back side of substrate 272, thereby releasing bottom surface of piezoelectric layer 240 of transducer device 204 through cavity 250. In some examples, the back side etch may be an anisotropic etch process. In an example, the back side etch may use a plasma-based etch process, such as a DRIE process, or a Bosch etch process. In another example, wet etch using an appropriate etchant (e.g., TMAH, HF or Hydrofluoric acid) may also be used. The etching of layer 248 can be performed with an etchant that does not etch (or etch at a much lower rate) filler layers 246 so that the anchor point and vent gap are not affected by the etching of layer 248.

In an example, after piezoelectric layer 240 is formed, the cantilever beam of the piezoelectric layer 240 can have an internal stress, such as a residual stress from deposition of piezoelectric layer 240. Once the cantilever beam of the piezoelectric layer 240 is released, this residual stress may cause the cantilever beam to bend on its own (e.g., upwards or downwards). Process parameters of the deposition process to deposit piezoelectric layer 240 can be controlled such that the cantilever beam of piezoelectric layer 240, after being released, has an intended final profile as shown in FIG. 7E, where the cantilever beam of piezoelectric layer 240 bends downward into cavity 250 at a native or nominal position without an external stress or an external actuation signal. Dotted lines 755 illustrate an example final profile of the cantilever beam of piezoelectric layer 240. With such arrangements, the vent gap distance can be defined, at a high precision, by the free end of the cantilever beam (which is aligned with the trench structures) and the exposed filler layer 242b of partial trench structure/recess 239b1. This gives a well-controlled vent gap distance and reduce uncertainty in, for example, the lower 3 dB frequency of the transducer device.

In an example, to cause the cantilever beam of piezoelectric layer 240 to bend downward, process parameters of the deposition process to deposit piezoelectric layer 240 are controlled. For example, a radio frequency (RF) power supplied during the deposition of these material may be controlled. In another example, a bias power provided during the deposition may be controlled. In another example, another parameter of the deposition may be controlled. Such controlling of the deposition process parameter allows control of residual stress profile within the deposited piezoelectric layer 240 in such a manner that causes downward bended profile of the cantilever beam of piezoelectric layer 240 after release.

Following are additional examples provided in view of the above-described implementations. Here, one or more features of example, in isolation or in combination, can be combined with one or more features of one or more other examples to form further examples also falling within the scope of the disclosure. As such, one implementation can be combined with one or more other implementation without changing the scope of disclosure.

Example 1. An apparatus comprising: a substrate of a first material having opposing first side and second side, the substrate including: a cavity that that extends from the second side; and a first layer and a second layer of a second material that extends from the first side of the substrate and forming at least parts of opposing side walls of the cavity, in which at least one of: the second material is different from the first material, or the substrate is separated from the first layer and the second layer by a layer of a third material different from the first material; and one or more devices on the first side of the substrate.

Example 2. The apparatus of example 1, wherein the first material and the second material are the same, and the substrate is separated from the first layer and the second layer by the layer of the third material.

Example 3. The apparatus of any of examples 1-2, wherein the one or more devices includes a transducer device, the transducer device includes a cantilever beam extending over the first layer and part of the cavity, and the apparatus includes a third layer over the second layer and opposing an end of the cantilever beam.

Example 4. The apparatus of example 3, wherein the transducer device includes a fixed portion and a wall portion, the cantilever beam is between the fixed portion and the wall portion, and the apparatus comprises a layer of a fourth material between the substrate and each of the fixed portion and the wall portion, in which the first layer and the second layer penetrate through the layer of the fourth material into the substrate.

Example 5. The apparatus of example 4, wherein the third material and the fourth material are the same.

Example 6. The apparatus of any of examples 4-5, wherein the third material and the fourth material includes an oxide.

Example 7. The apparatus of any of examples 3-6, wherein the cantilever beam bends down into the cavity at a native or nominal position without an external stress or an external actuation signal.

Example 8. The apparatus of example 7, wherein an end of the cantilever beam opposes the second layer at the native or nominal position.

Example 9. The apparatus of any of examples 3-8, wherein the cantilever beam includes a piezoelectric bimorph and electrodes.

Example 10. The apparatus of any of examples 3-9, wherein the substrate includes a post portion, the first layer of the second material is part of the post portion, and the cavity wraps at least partially around the post portion.

Example 11. The apparatus of example 10, wherein the cantilever beam wraps at least partially around the post portion.

Example 12. The apparatus of any of examples 10-11, wherein the cantilever beam is a first cantilever beam, and the apparatus further comprises a second cantilever beam extending over the first layer and the cavity.

Example 13. The apparatus of any of examples 3-12, wherein the substrate includes a post portion, the first layer of the second material is part of the post portion, the cavity is a first cavity on a first side of the post, and the substrate includes a second cavity on a second side of the post; wherein the apparatus includes a third layer and a fourth layer of the second material in the substrate and forming at least parts of opposing side walls of the second cavity, the third layer of the second material is part of the post portion; and wherein the cantilever beam is a first cantilever beam, and the apparatus further comprises a second cantilever beam extending over the third layer.

Example 14. The apparatus of any of examples 3-13, wherein the cantilever beam is part of at least one of: a microphone, a speaker, a micro mirror, or an accelerometer.

Example 15. The apparatus of any of examples 3-14, further comprising a reservoir between the transducer device and the cavity, the transducer device is configurable to exert a pressure into the reservoir to dispense a fluid from the reservoir through the cavity.

Example 16. The apparatus of any of examples 1-15, wherein the substrate includes first and second trench structures each filled with the second material, the first trench structure being adjacent to the first layer, the second trench structure being adjacent the second layer.

Example 17. The apparatus of example 16, wherein each of the first and second layers is part of a respective partial trench structure having parts of trench sidewalls removed.

Example 18. The apparatus of any of examples 16-17, wherein each of the first layer, the second layer, the first trench structure, and the second trench structure surrounds a periphery of the cavity.

Example 19. The apparatus of any of examples 16-18, wherein each of the first layer, the second layer, the first trench structure, and the second trench structure include discontinuous segments around a periphery of the cavity.

Example 20. The apparatus of any of examples 1-19, wherein the one or more devices includes a first device and a second device in the substrate, the first and second devices being separated by the cavity and the first and second layers of the second material.

Example 21. The apparatus of any of examples 1-20, wherein the substrate and the one or more devices are part of a packaged integrated circuit.

Example 21. A packaged integrated circuit comprising: a substrate of a first material having opposing first side and second side, the substrate including: a cavity that that extends from the second side; and a first layer and a second layer of a second material that extends from the first side of the substrate and forming at least parts of opposing side walls of the cavity, in which at least one of: the second material is different from the first material, or the substrate is separated from the first layer and the second layer by a layer of a third material different from the first material.

Example 22. The packaged integrated circuit of example 21, further comprising a transducer device on the first side of the substrate.

Example 23. A method comprising: forming a first trench structure and a second trench structure that extend from a first side of a substrate comprising a first material; filling the first and second trench structures with a second material; forming one or more device on the first side of the substrate; and forming a cavity that extend from a second side of the substrate to the first side by removing parts of the substrate between the first and second trench structures, in which the second material in the first and second trench structures form at least parts of opposing side walls of the cavity.

Example 24. The method of example 23, further comprising: forming a layer of a third material on the first side of the substrate, the first and second trench structures extending through the layer; and forming a layer of a fourth material on internal surfaces of the first and second trench structures, such that the liner layer is between the second material and the internal surfaces, wherein forming the cavity comprises: removing parts of the substrate between the first and second trench structures, removing parts of the layer of the third material between the first and second trench structures, and removing parts of the layer of the fourth material, such that parts of the second material in the first and second trench structures are exposed through the cavity.

Example 25. The method of example 24, wherein removing parts of the substrate and removing parts of the layer of the third material comprises: removing parts of the substrate during a first etch process and using a first etchant; and removing parts of the first layer during a second etch process and using a second etchant.

Example 26. The method of example 25, wherein removing parts of the layer of the fourth material comprises: removing parts of the layer of the fourth material during the second etch process and using the second etchant.

Besides what is described herein, various modifications can be made to disclose implementations and implementations thereof without departing from their scope. Therefore, illustrations of implementations herein should be construed as examples, and not restrictive to scope of present disclosure.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” or “configurable to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics, or semiconductor components.

A circuit or device that is described herein as including certain components may instead be adapted to be coupled to those components to form the described circuit or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuit. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be in depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN), or a gallium arsenide substrate (GaAs).

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately,” or “substantially” preceding a parameter means being within +/−10 percent of that parameter or, if the parameter is zero, a reasonable range of values around zero.

What is claimed is:

1. An apparatus comprising:
a substrate of a first material having opposing first side and second side, the substrate including:
a cavity that that extends from the second side; and
a first layer and a second layer of a second material that extends from the first side of the substrate and forming at least parts of opposing side walls of the cavity, in which at least one of: the second material is different from the first material, or the substrate is separated from the first layer and the second layer by a layer of a third material different from the first material; and
one or more devices on the first side of the substrate.

2. The apparatus of claim 1, wherein the first material and the second material are the same, and the substrate is separated from the first layer and the second layer by the layer of the third material.

3. The apparatus of claim 1, wherein the one or more devices includes a transducer device, the transducer device includes a cantilever beam extending over the first layer and part of the cavity, and the apparatus includes a third layer over the second layer and opposing an end of the cantilever beam.

4. The apparatus of claim 3, wherein the transducer device includes a fixed portion and a wall portion, the cantilever beam is between the fixed portion and the wall portion, and the apparatus comprises a layer of a fourth material between the substrate and each of the fixed portion and the wall portion, in which the first layer and the second layer penetrate through the layer of the fourth material into the substrate.

5. The apparatus of claim 4, wherein the third material and the fourth material are the same.

6. The apparatus of claim 4, wherein the third material and the fourth material includes an oxide.

7. The apparatus of claim 3, wherein the cantilever beam bends down into the cavity at a native or nominal position without an external stress or an external actuation signal.

8. The apparatus of claim 7, wherein an end of the cantilever beam opposes the second layer at the native or nominal position.

9. The apparatus of claim 3, wherein the cantilever beam includes a piezoelectric bimorph and electrodes.

10. The apparatus of claim 3, wherein the substrate includes a post portion, the first layer of the second material is part of the post portion, and the cavity wraps at least partially around the post portion.

11. The apparatus of claim 10, wherein the cantilever beam wraps at least partially around the post portion.

12. The apparatus of claim 10, wherein the cantilever beam is a first cantilever beam, and the apparatus further comprises a second cantilever beam extending over the first layer and the cavity.

13. The apparatus of claim 3, wherein the substrate includes a post portion, the first layer of the second material is part of the post portion, the cavity is a first cavity on a first side of the post, and the substrate includes a second cavity on a second side of the post;
wherein the apparatus includes a third layer and a fourth layer of the second material in the substrate and forming at least parts of opposing side walls of the second cavity, the third layer of the second material is part of the post portion; and
wherein the cantilever beam is a first cantilever beam, and the apparatus further comprises a second cantilever beam extending over the third layer.

14. The apparatus of claim 3, wherein the cantilever beam is part of at least one of: a microphone, a speaker, a micro mirror, or an accelerometer.

15. The apparatus of claim 3, further comprising a reservoir between the transducer device and the cavity, the transducer device is configurable to exert a pressure into the reservoir to dispense a fluid from the reservoir through the cavity.

16. The apparatus of claim 1, wherein the substrate includes first and second trench structures each filled with the second material, the first trench structure being adjacent to the first layer, the second trench structure being adjacent the second layer.

17. The apparatus of claim 16, wherein each of the first and second layers is part of a respective partial trench structure having parts of trench sidewalls removed.

18. The apparatus of claim 16, wherein each of the first layer, the second layer, the first trench structure, and the second trench structure surrounds a periphery of the cavity.

19. The apparatus of claim 16, wherein each of the first layer, the second layer, the first trench structure, and the second trench structure include discontinuous segments around a periphery of the cavity.

20. The apparatus of claim 1, wherein the one or more devices includes a first device and a second device in the substrate, the first and second devices being separated by the cavity and the first and second layers of the second material.

21. The apparatus of claim 1, wherein the substrate and the one or more devices are part of a packaged integrated circuit.

22. A packaged integrated circuit comprising:
a substrate of a first material having opposing first side and second side, the substrate including:
a cavity that that extends from the second side; and
a first layer and a second layer of a second material that extends from the first side of the substrate and forming at least parts of opposing side walls of the cavity, in which at least one of: the second material is different from the first material, or the substrate is separated from the first layer and the second layer by a layer of a third material different from the first material.

23. The packaged integrated circuit of claim 22, further comprising a transducer device on the first side of the substrate.

24. A method comprising:
forming a first trench structure and a second trench structure that extend from a first side of a substrate comprising a first material;
filling the first and second trench structures with a second material;
forming one or more device on the first side of the substrate; and
forming a cavity that extend from a second side of the substrate to the first side by removing parts of the substrate between the first and second trench structures, in which the second material in the first and second trench structures form at least parts of opposing side walls of the cavity.

25. The method of claim 24, further comprising:
forming a layer of a third material on the first side of the substrate, the first and second trench structures extending through the layer; and
forming a layer of a fourth material on internal surfaces of the first and second trench structures, such that the liner layer is between the second material and the internal surfaces,
wherein forming the cavity comprises:
removing parts of the substrate between the first and second trench structures,
removing parts of the layer of the third material between the first and second trench structures, and
removing parts of the layer of the fourth material, such that parts of the second material in the first and second trench structures are exposed through the cavity.

26. The method of claim 25, wherein removing parts of the substrate and removing parts of the layer of the third material comprises:
removing parts of the substrate during a first etch process and using a first etchant; and
removing parts of the first layer during a second etch process and using a second etchant.

27. The method of claim 26, wherein removing parts of the layer of the fourth material comprises:
removing parts of the layer of the fourth material during the second etch process and using the second etchant.
